(19) United States
(12) Patent Application Publication
(10) Pub. No.: US 2026/0214058 A1
(43) Pub. Date: Jul. 23, 2026

(54) Circuit and Method for Graceful Stop of Packet Transmission

(71) Applicant: Marvell Asia Pte Ltd, Singapore (SG)

(72) Inventors: Yaakov Yehezkel, Rehovot (IL); Amit Freedman, Yehud-Monosson (IL)

(21) Appl. No.: 19/453,759

(22) Filed: Jan. 20, 2026

Related U.S. Application Data
(60) Provisional application No. 63/748,234, filed on Jan. 22, 2025.

(51) Int. Cl. H04L 47/263; H04L 47/70

(52) U.S. Cl. CPC H04L 47/263; H04L 47/82

(57) ABSTRACT

A circuit and corresponding method stop packet transmission, gracefully. The circuit comprises a packet buffer (PB) with at least one queue, PB write logic, and PB read logic. In response to a stop command, the PB write logic marks a start of packet (SoP) word of a packet with a synchronization indicator to produce a marked SoP word written to a queue of the at least one queue of the PB and writes, to descriptor logic, packet-delimiters of words of the packet written to the queue. The stop command identifies the queue. The PB read logic reads from the descriptor logic based on reading the marked SoP word from the queue and stops reading from the queue based on reading an active end of packet (EoP) delimiter from the descriptor logic. Transmission of the packet from the queue is stopped in a graceful manner via the reading stopped.

### RELATED APPLICATION

This application claims the benefit of U.S. Provisional Application No. 63/748,234, filed on Jan. 22, 2025. The entire teachings of the above application are incorporated herein by reference.

### BACKGROUND

In the context of data transfer and communications protocols, SoP stands for Start of Packet and EoP stands for End of Packet. Typically, SoP and EoP packet delimiters, such as SoP and EoP signaling bits or control words, may be used to delimit a beginning word and an end word of a single, distinct packet of data being transmitted, such as over a physical interface or bus for non-limiting examples. Such SoP and EoP delimiters may be referred to simply as SoP and EoP delimiters or SoP and EoP delimiter attributes.

Such packet delimiters may be stored, for example, in a packet buffer (PB). A PB may be a shared memory storage, serving multiple queues, and storing both packet data and packet delimiters, namely the SoP and EoP delimiters. A single queue may store a sequence of ordered packets. The PB's basic storage unit may be a single data word with a fixed size, written along with its SoP and EoP delimiters.

Packet words may be referred to as data words or simply as words. Packet words may be read from the PB in response to receiving read grants (e.g., one read per grant) and transmitted. Each queue may transmit its own packets in perfect order, but between queues transmission may be interleaved, regardless of a current transmission state.

The SoP and EoP delimiters may be active or inactive, that is, each of such delimiters may be associated with an active state or inactive state. A word with an active SoP delimiter may be referred to as a SoP word and a word with an active EoP delimiter may be referred to as an EoP word.

### SUMMARY

According to an example embodiment, a circuit comprises a packet buffer (PB) with at least one queue and PB write logic. The PB write logic is configured, in response to a stop command, to mark a start of packet (SoP) word of a packet with a synchronization indicator to produce a marked SoP word written to a queue of the at least one queue of the PB and to write, to descriptor logic, packet-delimiters of words of the packet written to the queue. The stop command identifies the queue. The circuit further comprises PB read logic configured to read from the descriptor logic based on reading the marked SoP word from the queue of the PB and to stop reading from the queue based on reading an active end of packet (EoP) delimiter from the descriptor logic. Transmission of the packet from the queue is stopped in a graceful manner via the reading stopped. The graceful manner includes stopping the transmission at a packet boundary of the packet.

Each queue of the at least one queue of the PB may be a first-in first-out (FIFO) queue for non-limiting example.

The descriptor logic may include a descriptor FIFO for the queue. The PB read logic may include graceful stop logic. The graceful stop logic may be configured to read from the queue based on a read grant received for the queue and to initialize a read pointer of the descriptor FIFO based on reading the marked SoP word from the queue. The graceful stop logic may be further configured to read from the descriptor FIFO based on the read pointer initialized and to stop the reading from the queue based on reading the active EoP delimiter from the descriptor FIFO.

The PB read logic may include a delay buffer. The graceful stop logic may be further configured to initialize the read pointer by offsetting the read pointer from a base pointer of the descriptor FIFO. The offsetting may be based on a total number of ongoing reads for the queue represented by the delay buffer. The read pointer may be initialized to cause a next read from the descriptor FIFO to produce delimiters of a next word to be read from the queue.

The SoP word may have an active SoP delimiter. Transmission of an EoP word of the packet may represent the packet boundary. The EoP word may have the active EoP delimiter.

The circuit may comprise the descriptor logic. The PB may have a read latency. The descriptor FIFO may have a depth that is based on a total number of words of a maximum transmission unit (MTU) and a total number of cycles. The total number of cycles may represent the read latency of the PB.

The descriptor FIFO may be configured to contain respective SoP and EoP delimiters of each word written to the queue.

The descriptor FIFO may be a flip-flop (FF)-based descriptor FIFO. The descriptor logic may include a respective FF-based descriptor FIFO for each queue of the at least one queue of the PB.

The PB write logic may be configured to push to the descriptor FIFO, with each word written to the queue, respective SoP and EoP delimiters of each word written. The PB write logic may start pushing from a base of the descriptor FIFO. The PB write logic may be further configured to stop pushing to the descriptor FIFO in an event the descriptor FIFO is full.

The graceful stop logic may be configured to read from the queue based on a read grant received for the queue and to stop the reading from the queue by ignoring read grants received for the queue.

The delay buffer may be configured to indicate ongoing reads from the PB. A number of entries in the delay buffer may be based on a read latency of the PB. An entry of the delay buffer may be configured to represent a queue identifier of a respective queue of the PB for which a read is ongoing.

According to another example embodiment, a method comprises marking, in response to a stop command, a SoP word of a packet with a synchronization indicator to produce a marked SoP word written to a queue of at least one queue of a PB. The stop command identifies the queue. The method further comprises writing, to descriptor logic in response to the stop command, packet-delimiters of words of the packet written to the queue of the at least one queue. The method further comprises reading from the descriptor logic based on reading the marked SoP word from the queue of the PB. The method further comprises stopping reading from the queue based on reading an active EoP delimiter from the descriptor logic. Transmission of the packet from the queue is stopped in a graceful manner via the reading stopped. The graceful manner includes stopping the transmission at a packet boundary of the packet.

Further alternative method embodiments parallel those described above in connection with the example circuit embodiment.

According to another example embodiment, an apparatus comprises means for marking, in response to a stop command, a SoP word of a packet with a synchronization indicator to produce a marked SoP word written to a queue of at least one queue of a PB. The stop command identifies the queue. The apparatus further comprises means for writing to descriptor logic in response to the stop command, packet-delimiters of words of the packet written to the queue of the at least one queue. The apparatus further comprises means for reading from the descriptor logic based on reading the marked SoP word from the queue of the PB. The apparatus further comprises means to stop reading from the queue based on reading an active EoP delimiter from the descriptor logic. Transmission of the packet from the queue is stopped in a graceful manner via the reading stopped, the graceful manner includes stopping the transmission at a packet boundary of the packet.

Further alternative apparatus embodiments parallel those described above in connection with the example circuit embodiment.

According to another example embodiment, a system comprises a network interface and a device. The device includes a PB with at least one queue and PB write logic. The PB write logic is configured, in response to a stop command, to mark a SoP word of a packet with a synchronization indicator to produce a marked SoP word written to a queue of the at least one queue of the PB and to write, to descriptor logic, packet-delimiters of words of the packet written to the queue. The stop command identifies the queue. The device further comprises PB read logic configured to read from the descriptor logic based on reading the marked SoP word from the queue of the PB and to stop reading from the queue based on reading an active EoP delimiter from the descriptor logic. Transmission of the packet from the queue is stopped in a graceful manner via the reading stopped. The graceful manner includes stopping the transmission at a packet boundary of the packet.

The system may be a server of at least one server of a data center and the device may be a system-on-chip (SoC).

Further alternative system embodiments parallel those described above in connection with the example circuit embodiment.

According to another example embodiment, a hardware description language (HDL) design structure is encoded on a machine-readable data storage medium. The HDL design structure comprises elements that when processed in a computer-aided design system generate a machine-executable representation of a device. The HDL design structure comprises a PB with at least one queue and PB write logic. The PB write logic is configured, in response to a stop command, to mark a start of packet (SoP) word of a packet with a synchronization indicator to produce a marked SoP word written to a queue of the at least one queue of the PB and to write, to descriptor logic, packet-delimiters of words of the packet written to the queue, the stop command identifying the queue. The HDL design structure further comprises PB read logic configured to read from the descriptor logic based on reading the marked SoP word from the queue of the PB. The PB read logic is further configured to stop reading from the queue based on reading an active EoP delimiter from the descriptor logic. Transmission of the packet from the queue is stopped in a graceful manner via the reading stopped. The graceful manner includes stopping the transmission at a packet boundary of the packet.

Further alternative HDL design structure embodiments parallel those described above in connection with the example circuit embodiment.

It should be understood that example embodiments disclosed herein can be implemented in the form of a circuit, method, apparatus, system, or computer readable medium with program codes embodied thereon.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a block diagram of an example embodiment of a circuit.

FIG. 2 is a block diagram of another example embodiment of a circuit.

FIG. 3 is a state transition diagram of an example embodiment of a finite state machine.

FIG. 4 is a flow diagram of an example embodiment of a method.

FIG. 5 is a block diagram of an example embodiment of a data center.

### DETAILED DESCRIPTION

A description of example embodiments follows.

As disclosed above, a packet buffer (PB) may be a shared memory storage, serving multiple queues for writing and reading. Such queues may correspond to channels. A queue may be a first in first (FIFO) queue that may store both packet data and packet-controls, such as start of packet (SoP) and end of packet (EoP) delimiters. A single queue may represent a sequence of ordered packets, stored word by word, along with SoP and EoP delimiters per word. Packets may be read from the PB, word by word, that is, on a word-by-word basis, and transmitted word by word, keeping perfect order internal to any queue. A read grant may be received in a clock cycle, along with a queue identifier (QID) that may be a number that identifies a queue to be read. Timing of receipt of such read grants and their respective queue identifiers (QIDs) may be arbitrary from the PB's point of view, and unrelated to a transmitted packet boundary state of any queue. A read latency of the PB and width of data words read from the PB may have respective constant values that may be considered large, as disclosed further below.

An example embodiment disclosed herein may provide a hardware mechanism that may stop a queue from transmitting, further to a stop command, in a graceful manner, that is, at a packet boundary. No packet loss or packet truncation may be incurred. Once transmission of a packet has started, the hardware mechanism may ensure that the packet has been transmitted in its entirety, even though transmission of the queue storing the packet has been commanded to stop transmission. In addition, an example embodiment may support transmission for multiple queues to be stopped, simultaneously, in the graceful manner. For example, multiple queues may be in the process of stopping transmission at a packet boundary, in parallel. An example embodiment may implement such a hardware mechanism with minimal area cost to a circuit that includes same.

According to a first approach, stopping in the graceful manner may be implemented by adding a flip-flop (FF)-based output FIFO to absorb ongoing reads. For example, for each queue (e.g., Q[i]), a FIFO could be added, implemented as flip-flops (FFs), to absorb all read data from the PB belonging to Q[i], before transmitting it. Once a stop command is given to Q[i], transmission by Q[i] may be stopped after a closest (next) EoP word from Q[i] has been transmitted, and then reading from the Q[i] of the PB may be stopped immediately, ignoring further read grants for Q[i], and the output FIFO may absorb any ongoing reads. Immediate stopping of transmission may be supported because the output FIFO may be FF-based and, thus, the FIFO[head] may be visible in zero time. When the stop command is unset (de-asserted, cleared), reading from Q[i] of the PB may be resumed responsive to read grants, and data may be read from the PB for Q[i] and transmitted.

Such an implementation is lossless. Latency between a stop command being set (asserted) and an actual transmission stop may be minimal and attributed to transmitting a current packet. Latency between unsetting the stop command and resuming transmission may be none. While such an implementation may be intuitive and simple, it may be costly in terms of circuit area. For example, such an implementation employs an output FIFO per queue, for handling simultaneous queues'stop commands. Further, a size of each output FIFO may be large: <read latency>×<word width>, that is, a depth of each per queue output FIFO may be a product of the read-latency of the PB and a width of a data word. Thus, while lossless, use of such an output FIFO is expensive in terms of area cost, considering a large data word width and duplication of the output FIFO per queue. As such, the implementation does not scale.

According to a second approach, the graceful manner could be implemented by stopping read commands from being issued to a queue after transmission of an EoP from the queue and then discarding data for any ongoing reads from the queue, if they exist. For example, once a stop command is received for Q[i], transmission by Q[i] may be stopped after the closest (next) EoP from Q[i] has been transmitted and then reading of Q[i] from the PB may be stopped immediately, ignoring further Q[i] grants. In this implementation, data words returned from ongoing reads are discarded. A packet would either be fully discarded or fully transmitted (no truncation allowed) and, thus, a packet-drop state may be maintained for the current packet of each queue. When the stop command is unset, such an implementation may finish discarding a current packet (if any) being read for transmission and then revert to normal transmission. Such an implementation may have a very low area cost; however, the implementation is lossy.

Specifically, with reference to the very low area cost, the implementation would maintain two state bits per queue, namely current-packetdelineation (SoP/EoP), and current-packet-drop. Latency between a stop command and an actual transmission stop may be minimal and attributed to completing transmission of a current packet. Latency between receipt of a stop command unset, that is, a resume command, and transmission resuming may correspond to a transmission time for transmitting a maximum transmission unit (MTU) to finish discard of a current packet. With reference to being lossy, a total maximum number of packets that can be discarded may be equal to a read latency of the PB: all ongoing reads might belong to Q[i], each containing a minimally sized packet (SoP/EoP=1), and all would be discarded. As such, a maximum amount of data that may be discarded is ~MTU.

In contrast to the first and second approaches described above, an example embodiment of a circuit disclosed herein advantageously implements the graceful manner, without packet loss or corruption, and with minimal area cost to the circuit. An example embodiment may enable same by adding PB write logic and PB read logic to make packet delimiters known in advance, before issuing read commands to a queue of the PB. In this way, issuing read commands to the queue of the PB can be stopped precisely at SoP and will avoid having any extra ongoing reads in progress after transmission from the queue (Q[i]) is stopped.

Further to a stop command being issued for Q[i], an example embodiment of the PB write logic may mark a next written SoP word to the Q[i] with a special marking to denote the packet as a synchronization packet. An example embodiment of a circuit comprising such PB write logic may use descriptor logic which may, for non-limiting example, be a dedicated FF-based descriptor-FIFO of depth <MTU_words+read_latency>, where MTU_words represents the MTU in words, that is, a total maximum number of words of a largest packet size that can be handled in a single transmission, and read_latency represents a read latency of the PB, According to an example embedment, the SoP and EoP delimiters may be pushed to the descriptor logic with each write to the Q[i], until it becomes full. Such description logic (e.g., FF-based FIFO) may include the delimiters (SoP, EoP) of each written word to the Q[i] of the PB responsive to the marking.

According to an example embodiment, the PB read logic may denote a time of marking the SoP of Q[i] as a synchronization point and, when the marked SoP of Q[i] is output from the PB, that is, read by the PB read logic, an exact location (e.g., read-pointer offset) in the descriptor logic (e,g,, descriptor-FIFO) can be determined that matches a next read to be performed from the Q[i] of the PB. Then, with each read grant that follows, the PB read logic may continue reading from both the Q[i] of the PB and the descriptor logic, until an EoP is indicated by the descriptor logic, at which point the PB read logic may stop issuing read commands to the PB for Q[i]. All words read from the PB may be transmitted immediately, and no ongoing reads would need to be absorbed or dropped.

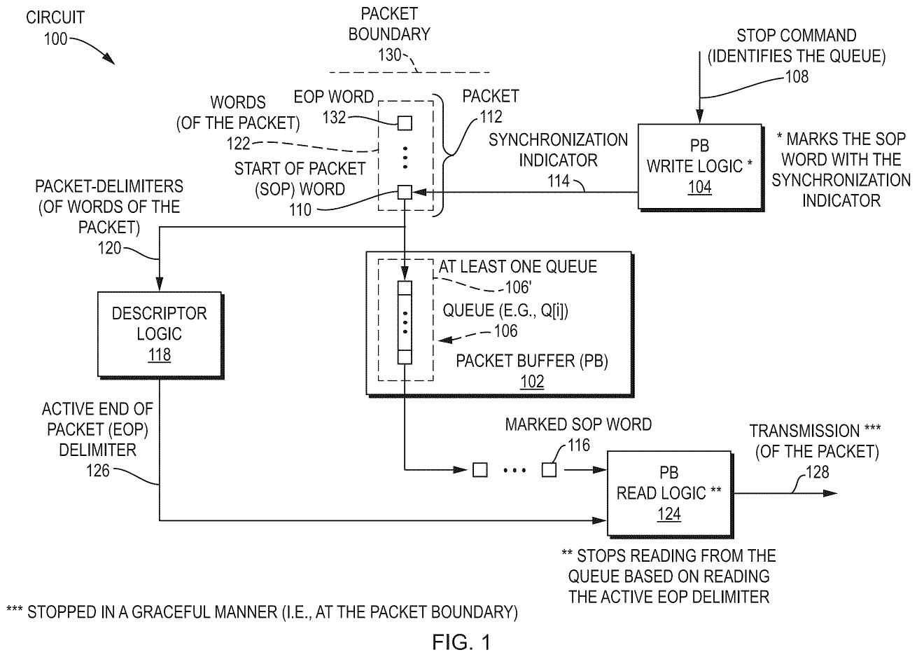

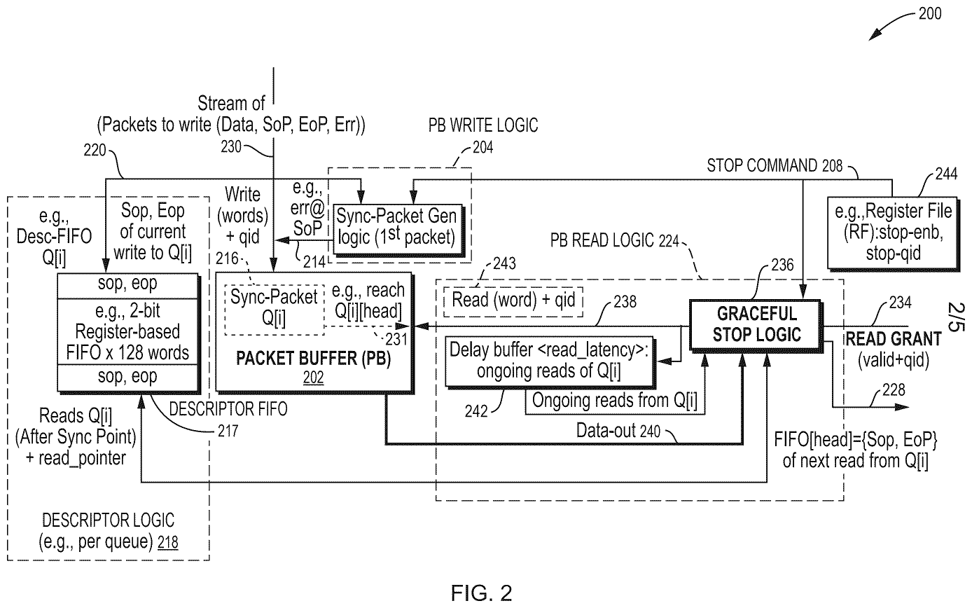

As such, an example embodiment of a circuit disclosed herein may provide means for hardware to temporarily stop traffic on specific queue(s), in a graceful manner, while being lossless and implemented with an area cost that is small (not proportional to data word width). Such a circuit may be utilized for congestion handling, to support queue-flush of downstream units, or for debug. During a stop state of a Q[i] of the PB, the Q[i] may include only full packets, which is better for analysis and debug. Also, further to a stop command for Q[i] being cleared, read and transmission for Q[i] can resume immediately upon a next read grant. An example embodiment of a circuit with such a hardware mechanism is disclosed below with reference to FIG. 1 and FIG. 2.

FIG. 1 is a block diagram of an example embodiment of a circuit 100. The circuit 100 may comprise a packet buffer (PB) 102 with at least one queue 106′. The circuit 100 may further comprise PB write logic 104 configured, in response to a stop command 108, to mark a start of packet (SoP) word 110 of a packet 112 with a synchronization indicator 114 to produce a marked SoP word 116 written to a queue 106 of the at least one queue 106′ of the PB 102 and to write, to descriptor logic 118, packet-delimiters 120 of words 122 of the packet 112 written to the queue 106. The stop command 108 may identify the queue 106. The circuit 100 may further comprise PB read logic 124 configured to read from the descriptor logic 118 based on reading the marked SoP word 116 from the queue 106 of the PB 102 and to stop reading from the queue 106 based on reading an active end of packet (EoP) delimiter 126 from the descriptor logic 118. Transmission 128 of the packet 112 from the queue 106 may be stopped in a graceful manner via the reading stopped. The graceful manner may include stopping the transmission 128 at a packet boundary 130 of the packet 112.

The SoP word 110 may have an active SoP delimiter, transmission of an EoP word 132 of the packet 112 from the circuit 100 may represent the packet boundary 130, and the EoP word 132 may have the active EoP delimiter 126.

For non-limiting example, a width of the data word may be large (e.g., 1024 bits for non-limiting example). As such, an implementation involving area cost proportional to data word width would be too expensive, especially if multiplied to all queues. The circuit 100 avoids same.

A minimum packet size may be 64 Bytes, hence contained in a single word (in which case, both SoP and EoP delimiters would be set). A size of the MTU may be ~9K Bytes. Both the minimum packet size and maximum packet size may be supported by the circuit 100.

In the circuit 100, a packet start (marked SoP word 116) may always be aligned to a word start, that is, each word in the PB 102 may contain a single packet's data. Storage in the PB 102 may be allocated, dynamically, hence a single queue may occupy the entire PB 102 at a given time. The circuit 100 may prevent a stop of transmission from being applied in the middle of a packet's transmission. As disclosed above, the transmission 128 of a packet may be stopped in the graceful manner. The circuit 200 of FIG. 2, disclosed below, also stops transmission in the graceful manner, as disclosed below.

FIG. 2 is a block diagram of another example embodiment of a circuit 200. The circuit 200 may be implemented as the circuit 100 of FIG. 1, disclosed above. Continuing with reference to FIG. 1 and FIG. 2, the circuit 200 may comprise a PB 202 with at least one queue 106′. The circuit 200 may further comprise PB write logic 204 configured, in response to a stop command 208, to mark a SoP word 110 of a packet 112 with a synchronization indicator 214 to produce a marked SoP word 216 written to a queue 106 of the at least one queue 106′ of the PB 202 and to write, to descriptor logic 218, packet-delimiters 220 of words 122 of the packet 112 written to the queue 106. The packet 112 may be from a stream 230 of packets to write to the PB 202 with words of the packets having respective packet-delimiters that represent an active state or inactive state for SoP and EoP delimiters.

Each queue of the at least one queue 106′ of the PB (102, 202) may be a first-in first-out (FIFO) queue for non-limiting example.

The descriptor logic (118, 218) may include a descriptor FIFO 217 for the queue 106. The PB read logic (124, 224) may include graceful stop logic 236. The graceful stop logic 236 may be configured to read from the queue 106 based on a read grant 234 received for the queue 106 and to initialize a read pointer (not shown) of the descriptor FIFO 217 based on reading the marked SoP word (116, 216) from the queue 106. The graceful stop logic 236 may be further configured to read from the descriptor FIFO 217 based on the read pointer initialized and to stop the reading from the queue 106 based on reading the active EoP delimiter 126 from the descriptor FIFO 217.

The PB read logic (124, 224) may include a delay buffer 242. The delay buffer 242 may be a shift register for non-limiting example. The graceful stop logic 236 may be further configured to initialize the read pointer by offsetting the read pointer from a base pointer (not shown) of the descriptor FIFO 217. The offsetting may be based on a total number of ongoing reads for the queue 106 represented by the delay buffer 242. The read pointer may be initialized to cause a next read from the descriptor FIFO 217 to produce delimiters of a next word to be read from the queue 106.

The SoP word 110 may have an active SoP delimiter. Transmission of an EoP word 132 of the packet 112 from the graceful stop logic 236 may represent the packet boundary 130. The EoP word 132 may have the active EoP delimiter 126.

The circuit (100, 200) may comprise the descriptor logic (118, 218). The PB (102, 202) may have a read latency. The descriptor FIFO 217 may have a depth that is based on a total number of words of a MTU and a total number of cycles. The total number of cycles may represent the read latency of the PB (102, 202).

The descriptor FIFO 217 may be configured to contain respective SoP and EoP delimiters of each word written to the queue 106. The descriptor FIFO 217 may be a flip-flop (FF)-based descriptor FIFO. The descriptor logic 217 may include a respective FF-based descriptor FIFO for each queue of the at least one queue 106′ of the PB (102, 202).

The PB write logic (104, 204) may be configured to push to the descriptor FIFO 217, with each word written to the queue 106, respective SoP and EoP delimiters of each word written. The PB write logic (104, 204) may start pushing from a base of the descriptor FIFO 217. The PB write logic (104, 204) may be further configured to stop pushing to the descriptor FIFO 217 in an event the descriptor FIFO 217 is full.

The graceful stop logic 236 may be configured to read from the queue 106 based on a read grant 234 received for the queue 106 and to stop the reading from the queue 106 by ignoring read grants, such as the read grant 234, received for the queue 106.

The delay buffer 242 may be configured to indicate ongoing reads from the PB (102, 202). A total number of entries in the delay buffer 242 may be based on a read latency of the PB (102, 202). An entry of the delay buffer 242 may be configured to represent a queue identifier of a respective queue of the PB (102, 202) for which a read is ongoing, that is, the read command 238 was issued but the data-out 240 corresponding to the read command 238 has not yet been provided.

Each word of a packet may be associated with a queue identifier (QID, qid) configured to identify a particular queue of the at least one queue 106′ for storing the word. The stop command 208 may identify the queue 106. The circuit 200 may further comprise PB read logic 224 configured to read from the descriptor logic 218 based on reading the marked SoP word 216 (i.e., sync-packet Q[i], where i is an identifier (ID) of the queue (Q)) from the queue 106 (i.e., Q[i]) of the PB 202. For non-limiting example, the queue 106 may be a FIFO with a head and a tail and the marked SoP word 216 may be read from the queue 106, that is Q[i], based on the marked SoP word 216 reaching 231 the head of Q[i], that is, a head of the queue 106. The PB read logic 224 may be configured to stop reading from the queue 106 of the PB 202 based on reading an active end of packet (EoP) delimiter 126 from the descriptor logic 218, in advance of reading the EoP delimiter 126 from Q[i] of the PB 202 due to the read latency of the PB 202. Transmission 228 of the packet 112 from the queue 106 of the PB 202 may be stopped in a graceful manner via the reading stopped. The graceful manner may include stopping the transmission 228 at the packet boundary 130 of the packet 112.

In the example embodiment of FIG. 2, reading from PB 202 may be done in a time-division multiplexing (TDM) fashion: each clock cycle (e.g., on a cycle-by-cycle basis). A TDM slice may be granted to a specific queue (or to none) on the cycle-by-cycle basis. Each queue may correspond to a respective channel. Slice grants are not known in advance; rather, they are given spontaneously from a point of view of the PB 202. Such slice grants may be issued by a consumer TDM system (not shown) and the stream 230 may be provided by a producer TDM system (not shown). The producer TDM system and consumer TDM system may write to the circuit 200 and read from the circuit 200, respectively, in accordance with their respective calendars for scheduling such writes and reads, independently with respect to one another.

As such, reading from the queue 106 of the PB 202 may be in response to receiving a read grant 234 that species a respective QID for the queue 106 and indicates that the read grant 234 is valid, and such a read grant may be received from the consumer TDM system for non-limiting example. In response to receiving the read grant 234 (e.g., a TDM grant, TDM read grant, or other read grant) for the queue 106, the circuit 200 may employ the PB read logic 224 to read a next word from the queue 106 of the PB 202

The PB read logic 224 may include graceful stop logic 236. Read latency from the PB 202 may be a non-zero read latency and such non-zero read latency may be potentially large (e.g., ~7 cycles for non-limiting example). The graceful stop logic 236 may be configured to issue a read command 238 to the PB 202. The read command 238 may represent a command to read a data word from a queue, such as the queue 106, identified by a QID. Further to the PB 202 receiving the read command 238, both the data word and its delimiters would be visible as the data-out 240 after the read latency (e.g., a number of cycles) and, thus, read by the graceful stop logic 236. The data-out 240 would then, in turn, be transmitted by the graceful stop logic 236 to a consumer, such as the consumer TDM system for non-limiting example. The PB read logic 224 and, more specifically, the graceful stop logic 235, has no prior knowledge of the expected data-out 240 (data word or its delimiters) at the time of sending the read command 238.

The circuit 200 comprises the PB write logic 104 and the PB read logic 124 and makes packet delimiters known in advance (before issuing read commands). In this way, a read from Q[i] of the PB 202 can be stopped precisely at SoP, avoiding any extra ongoing reads upon stop transmission time.

Once the stop command 108 is issued specifying Q[i], the PB write logic 204 may mark the closest written SoP of Q[i] with a special marking, namely, the synchronization indicator 214. The circuit 200 may further comprise the description logic 118 that may include a descriptor FIFO 217 for each queue of the at least one queue 106′ of the PB 202. As such, the descriptor FIFO 217 may be referred to as a per-queue descriptor FIFO. The descriptor FIFO 217 may be a per-queue dedicated FF-based descriptor-FIFO of depth <MTU_#words+read_latency>. The descriptor FIFO 217 may be pushed with each write to Q[i] in the PB 202 starting from FIFO[base], until the descriptor FIFO 217 is full, thereby avoiding overflowing the descriptor FIFO 217. This descriptor FIFO 217 (e.g., FIFO[i]) will contain the delimiters (SoP, EoP) of every written word to Q[i] of the PB 202.

When the marked SoP 116 of Q[i] is output as the data-out 240 (transmission side), it allows the PB read logic 224 to synchronize to the delimiters of each read-word, in advance. This event may be denoted as a synchronization point. In response to detecting the synchronization point, that is reading the marked SoP 116 from Q[i] of the PB, the graceful stop logic 236 may set rdPtr (read pointer) to a calculated offset in the descriptor-FIFO 217 (between FIFO[head] and FIFO[head +rd_latency]), and advance the rdPtr with every further read-command 238 to Q[i] hereon. The FIFO[rdPtr] will now indicate the expected delimiters of the next word to be read from Q[i].

The graceful stop logic 236 may stop reading from Q[i] after the closest EoP is read. All words that had been read until this point will be transmitted, but transmission is assured to stop at the packet boundary 130, since reading from Q[i] is stopped after reading the EoP word 132 from Q[i] and the circuit 200 may stop writing to the descriptor FIFO 217 that corresponds to Q[i]. Once the stop command 208 is unset for Q[i], reading from Q[i] can continue immediately upon the next read grant 234 for Q[i].

The area cost for the circuit 200 may be minimal. Specifically, in order to be able to calculate rdPtr at the point of synchronization, the delay buffer 242 of size 2×<read latency>, may be employed to register ongoing (in-flight) reads of Q[i] and may have a size that is ~14 bits for non-limiting example. A total depth of the descriptor-FIFO 217 may be large enough to accommodate a single MTU, plus #ongoing reads (the sum of which represents a total number of cycles between the synchronization point and an actual readstop). According to a non-limiting example, a size of the descriptor FIFO 217 may be less than 200 bits.

A latency between the stop command 208 and actual transmission stop may be equal to PB_size_#words+MTU_#words (the PB_size factor is because the marked packet is pushed to queue-tail, while read is done from queue-head). A single queue might occupy the entire PB 202 at any given moment, thereby adding the full PB size read delay until reaching the synchronization point.

The circuit 100 and circuit 200 provide an efficient stop mechanism, with zero extra noise to the system (graceful, no drops or truncations, per-queue activation at any time). Example embodiments of such circuits provide means for hardware to temporarily stop traffic on specific queue(s), and can be utilized for congestion handling, to support queue-flush of downstream units, or for debug.

With reference to FIG. 1 and FIG. 2, the small area cost for implementing the graceful manner in the circuit (100, 200) may include a fixed (small) cost per queue that does not depend on a total size of the PB (100, 200) or on dataword width. This allows such an implementation to be scaled and, thus, enables simultaneous stop commands to be handled for multiple queues. Latency between a stop command clear (unset) and transmission resuming may be none.

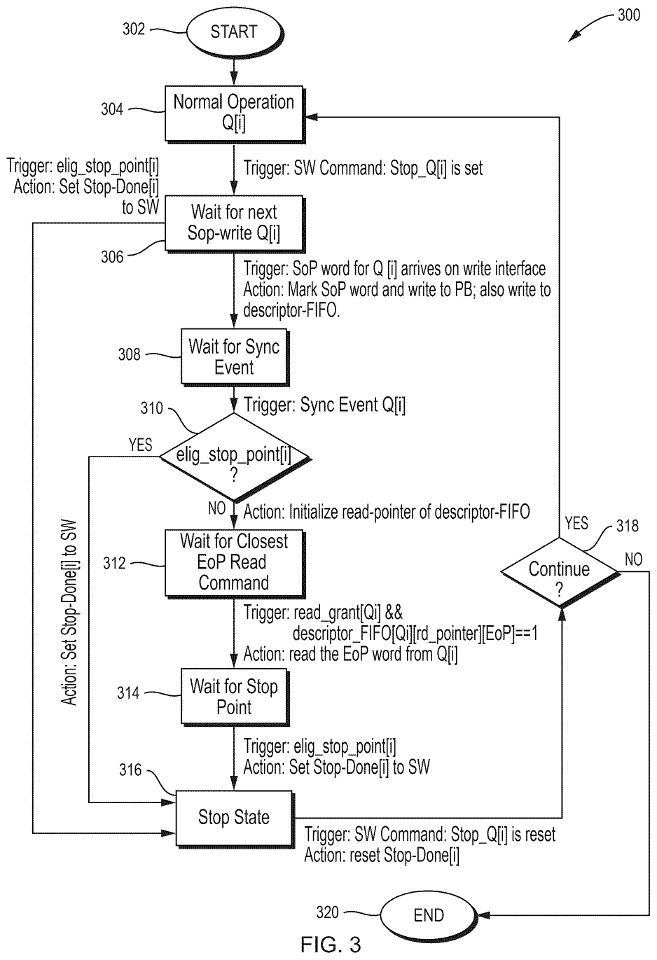

During a stop state, the PB (100, 200) may contain only full packets, which is simpler for analysis and debug. The circuits (100, 200) do not drop or truncate packets. A stop point for Q[i] of the PB (100, 200) is deterministic, depending on the fixed read-latency of the PB (102, 202) and a visible synchronization indicator (114, 214) of the marked SoP 116 output from the PB (100, 200). Further technical details of the circuits (100, 200) are disclosed below with reference to FIG. 3.

FIG. 3 is a state transition diagram 300 of an example embodiment of a finite state machine (FSM) that may be implemented by the circuit 100 or circuit 200 disclosed above with reference to FIG. 1 and FIG. 2, respectively. With reference to FIGS. 1-3, such a FSM may be implemented by the circuit (100, 200) per queue (i.e., Q[i]) of the PB (102, 202). In the state transition diagram 300, the annotation “trigger” denotes a state-transition trigger and a corresponding annotation “action” denotes action(s) taken upon the state-transition.

Continuing with reference to FIGS. 1-3, the FSM begins (302) and proceeds with normal operation (304). During normal operation (304), packets may be written to the PB (102, 202) as they arrive and may be read from the PB (102, 202) by the graceful stop logic 236 when Q[i] receives a read grant 234 and is not empty. Each word that is read from Q[i] may include data and control attributes related to it, namely values that represent an active or inactive state for SoP and EoP delimiters for the data (word). Writes to PB (102, 202) may be done in a “push” mode, so they are never refused or stopped by the PB (102, 202), in any state. On the read side of the PB (102, 202), namely a read interface/port, the PB (102, 202) has a constant latency denoted as rd_lat, read_latency, or read latency, and, thus, the data-out 240 that corresponds to the read command 238 is not visible until after rd_lat clock cycles have transpired after the read command 238 is given (issued). Also, throughout the entire time (at any state), the single delay buffer 242 (shift reg) may register the last rd_lat reads from PB (102, 202), denoted as “ongoing reads,” and it may do so by saving the read indication (1 bit wide) and the QID (log 2(#Qs) bits wide), which may be parameters 243 of the read command 238.

During normal operation (304), the stop command 208 may be issued. For example, a controller (not shown), such as a processor for non-limiting example, may set a bit (e.g., Stop_Q[i]) in a register file (RF) 244 corresponding to Q[i] to issue the stop command 208 for Q[i] for non-limiting example. The stop command 208 may be referred to as a software (SW) command. Based on the stop command 208 being issued, normal operation of Q[i] may continue, while waiting (306) for the next SoP word for Q[i] to arrive, or for an eligible stop point of Q[i], whichever happens first.

The eligible stop point of Q[i] may be referred to as elig_stop_point[i] and, in this state, namely waiting (306), the eligible stop point may mean that a last transmitted word from Q[i] was EoP, that is, the last transmitted word had a related EoP delimiter in an active state, and that there are no ongoing reads from Q[i]—as indicated by the delay buffer 242. If the eligible stop point of Q[i] is detected, the FSM may set a flag (stop_done[i]) for the processor to read, and such flag may be configured to indicate that Q[i] is in a stop state, and the FSM may transition to the stop state (316).

In the stop state (316), no reads are done from Q[i]. If a resume command is issued, that is, if Stop_Q[i] is reset (de-asserted, inactive), a check (318) for whether to continue may be made. If yes, the FSM may return to normal operation (304). If no, operation of the FSM thereafter ends (320) in the example embodiment.

If, however, while waiting (306) for the next SoP word for Q[i] to arrive; the SoP word 110 arrives on a write interface (not shown) of the circuit (100, 200) for Q[i]. The PB write logic 204 may mark the SoP word 110 with the synchronization indicator 214 and may write the marked SoP word to the PB (102, 202). The PB write logic 204 may also write the delimiters corresponding to the SoP word and, thus, the marked SoP word, in parallel, to the descriptor FIFO 217 of the descriptor logic (118, 218) that corresponds to Q[i]. The descriptor logic (118, 218) may be a descriptor FIFO for Q[i]. The delimiters may be written to Q[i]'s descriptor-FIFO's base address (with SoP bit set). The descriptor FIFO 217 may be a dedicated per-queue FIFO and writes to the descriptor-FIFO 217 may be done with zero latency (1 clock cycle), as the descriptor FIFO 217 may be implemented in D flip-flops (FFs).

Marking of the SoP word 110 may be done by setting a spare bit in its control field or by setting an error bit in the control field for non-limiting examples. The error bit may be used to represent the synchronization indicator 214 since the error bit may be an unused bit when the SoP delimiter is active and, thus, its use may be overloaded.

Following such marking and writing to the descriptor FIFO 217, the FSM may wait (308) for a synchronization event (synch event). While waiting for the synch event, with each Q[i] write operation, a parallel write may be done to the descriptor FIFO 217 (descriptor FIFO[i]) with the word's SoP and EoP delimiter attributes, unless the descriptor FIFO[i] reaches a full state, in which case the FSM stops writing to it. The synchronization event may be detected when the data-out 240 is the marked-SoP word of Q[i].

Further to detection of such a synchronization event, the FSM may check (310) for whether an eligible stopping point (elig_stop_point[i]) is present. For the elig_stop_point[i] to happen upon the synchronization event, it means that both: the marked-SoP word 116 was also an EoP word (indicating a short packet), and the delay buffer 242 did not indicate any ongoing reads from Q[i], that is, the delay buffer 242 did not have any instances of identifiers that correspond to Q[i].

If the eligible stop point of Q[i] is detected, the FSM may set a flag (stop_done[i]) for the processor to read, and such flag may be configured to indicate that Q[i] is in a stop state, and the FSM may transition to the stop state (316) and proceed, as disclosed above. If, however, the eligible stop state is not detected, the FSM may initialize the descriptor-FIFO[i]'s read pointer to <base_pointer+number_of_ongoing_reads[Qi]>. From then on, the descriptor FIFO head's contents contain the delimiters (attributes) of the next word to be read from the PB (102, 202). The descriptor-FIFO's output is available in zero time as it is implemented in DFFs (i.e., no need to pop the FIFO to see FIFO head's contents). Initializing the FIFO's read pointer is done with zero latency (1 clock cycle).

The FSM may then wait (312) for a closest (next immediate) EoP to be read and, while waiting, reading from Q[i] may continue, provided the next word to read is not an EoP word (as indicated by descriptor-FIFO[i]'s head). With every read of a Q[i] word from the PB (102, 202), triggered by a read grant 234 for Q[i], the graceful stop logic 236 may read (pop) one entry from the descriptor FIFO[i] (descriptor FIFO 217) and a pop from the descriptor FIFO 217 may be done with zero latency. The last read from Q[i] will be the EoP word 132, upon which the FSM may transition to wait (314) for the stop point for Q[i]. During the wait (314), no more reads of Q[i} are performed; however, all words output by the PB (102, 202) for all ongoing reads are transmitted and the FSM may transition to the stop state (316) in which no reads from Q[i] are performed and the FSM may proceed, as disclosed above.

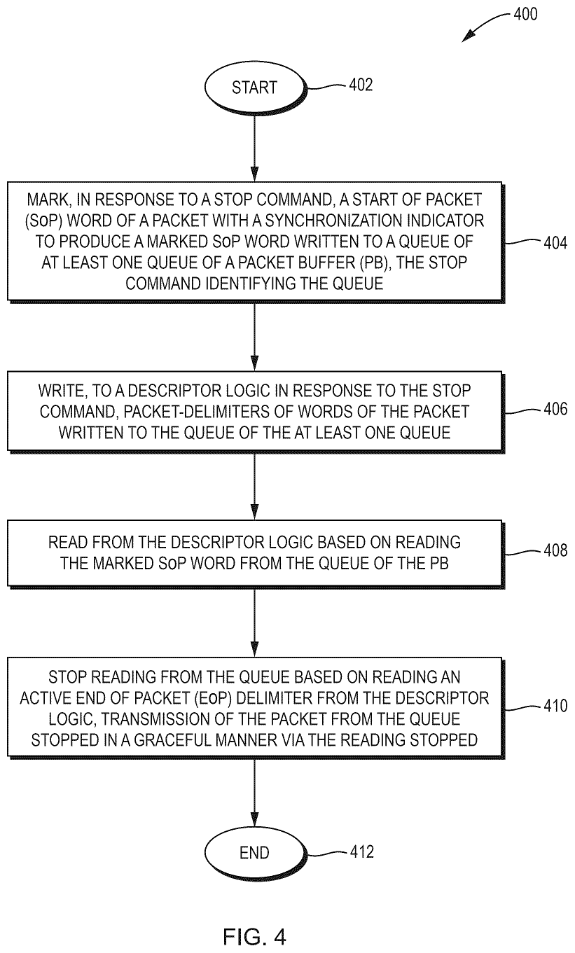

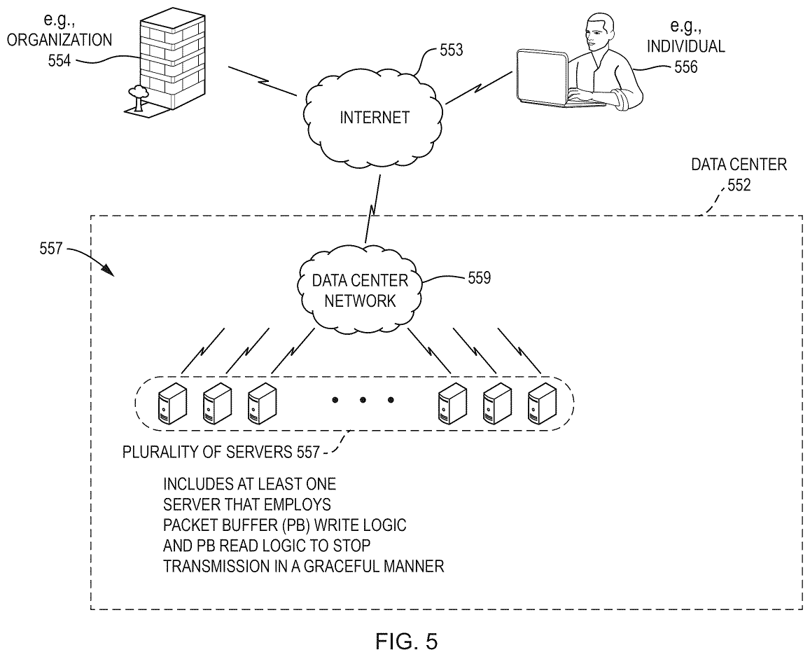

FIG. 4 is a flow diagram 400 of an example embodiment of a method. The method may begin (402) and comprise marking, in response to a stop command, a SoP word of a packet with a synchronization indicator to produce a marked SoP word written to a queue of at least one queue of a PB (404). The stop command may identify the queue. The method may further comprise writing, to descriptor logic in response to the stop command, packet-delimiters of words of the packet written to the queue of the at least one queue (406). The method may further comprise reading from the descriptor logic based on reading the marked SoP word from the queue of the PB (408). The method may further comprise stopping reading from the queue based on reading an active EoP delimiter from the descriptor logic, transmission of the packet from the queue may be stopped in a graceful manner via the reading stopped, the graceful manner including stopping the transmission at a packet boundary of the packet (410). The method thereafter ends (412) in the example embodiment. Such an example embodiment may be employed in a server of a data center for non-limiting example, such as the data center disclosed below with regard to FIG. 5 for non-limiting example.

FIG. 5 is a block diagram of an example embodiment of a data center 552. The data center 552 may have consumers that are entities, such as the organization 554, namely a business, and the individual 556 for non-limiting examples. Such consumers may utilize services (not shown) and an infrastructure 557 provided by the data center 552 for storing, processing, and accessing data (not shown) and applications (not shown).

In the data center 552, a plurality of servers 557 may function as core computing resources, responsible for storing, processing, and managing data, applications, and services, forming a backbone of the infrastructure 557. Consumers, such as the organization 554 and individual 556, may utilize such computing resources via the Internet 553 coupled to a data center network 559 of the data center 552 for non-limiting example. The plurality of servers 557 may store and manage vast amounts of data, acting as repositories for information that the consumers may rely on. Servers of the plurality of servers 557 may host various applications, from web servers delivering content, to database servers managing data. Servers of the plurality of servers 557 may provide services, such as email and network management, enabling users to access and utilize resources for non-limiting examples.

Servers of the plurality of servers 557 may provide processing power and memory for running applications and handling data requests. Servers of the plurality of servers 557 may be interconnected within the data center network 559, facilitating communication and data transfer between different systems. Servers of the plurality of servers 557 may be used for data center security, with dedicated servers acting as firewalls, intrusion detection systems, and virtual private network (VPN) gateways for non-limiting examples. Servers of the plurality of servers 557 may be used for backing up data and facilitating disaster recovery. As such, in the data center 552, graceful stop of packet transmission is useful for ensuring data integrity for storing, managing, and processing information. In the data center 552, at least one server of the plurality of servers 557 may employ an example embodiment of a device as disclosed below.

According to an example embodiment, a system, such as a server of the plurality of servers 557, may comprise a network interface (not shown) and a device, such as a system on chip (SoC) (not shown) for non-limiting example. Continuing with reference to FIG. 1, FIG. 2, and FIG. 5, the device may be the circuit (100, 200) implemented as an integrated circuit (IC) for non-limiting example. The device, of the server of at least one server of the plurality of servers 557, may include a PB (102, 202) with at least one queue 106′ and PB write logic (104, 204). The PB write logic (104, 204) may be configured, in response to a stop command (108, 208), to mark a SoP word 110 of a packet 112 with a synchronization indicator (114, 214) to produce a marked SoP word (116, 216) written to a queue 106 of the at least one queue 106′ of the PB (102, 202) and to write, to descriptor logic (118, 218), packet-delimiters (120, 220) of words 122 of the packet 112 written to the queue 106. The stop command (108, 208) may identify the queue 106. The circuit (100, 200) may further comprise PB read logic (124, 224) configured to read from the descriptor logic (118, 218) based on reading the marked SoP word (116, 216) from the queue 106 of the PB (102, 202) and to stop reading from the queue 106 based on reading an active EoP delimiter 126 from the descriptor logic (118, 218). Transmission (128, 228) of the packet 112 from the queue 106 may be stopped in a graceful manner via the reading stopped. The graceful manner may include stopping the transmission (128, 228) at a packet boundary 130 of the packet 112.

According to another example embodiment, a hardware description language (HDL) design structure (not shown) may be encoded on a machine-readable data storage medium. The HDL design structure may comprise elements that when processed in a computer-aided design system (not shown) generate a machine-executable representation of a device (not shown).

With reference to FIG. 1 and FIG. 2, the HDL design structure may comprise a PB (102, 202) with at least one queue 106′ and PB write logic (104, 204). The PB write logic (104, 204) may be configured, in response to a stop command (108, 208), to mark a SoP word 110 of a packet 112 with a synchronization indicator (114, 214) to produce a marked SoP word (116, 216) written to a queue 106 of the at least one queue 106′ of the PB (102, 202) and to write, to descriptor logic (118, 218), packet-delimiters (120, 220) of words 122 of the packet 112 written to the queue 106. The stop command (108, 208) may identify the queue 106. The circuit (100, 200) may further comprise PB read logic (124, 224) configured to read from the descriptor logic (118, 218) based on reading the marked SoP word (116, 216) from the queue 106 of the PB (102, 202) and to stop reading from the queue 106 based on reading an active EoP delimiter 126 from the descriptor logic (118, 218). Transmission (128, 228) of the packet 112 from the queue 106 may be stopped in a graceful manner via the reading stopped. The graceful manner may include stopping the transmission (128, 228) at a packet boundary 130 of the packet 112.

Further example embodiments disclosed herein may be configured using a computer program product; for example, controls may be programmed in software for implementing example embodiments. Further example embodiments may include a non-transitory computer-readable-medium that contains instructions that may be executed by a processor, and, when loaded and executed, cause the processor to complete methods described herein. It should be understood that elements of the block and flow diagrams may be implemented in software or hardware, firmware, a combination thereof, or other similar implementation determined in the future. In addition, the elements of the block and flow diagrams described herein may be combined or divided in any manner in software, hardware, or firmware. If implemented in software, the software may be written in any language that can support the example embodiments disclosed herein. The software may be stored in any form of computer readable medium, such as random-access memory (RAM), read only memory (ROM), compact disk read-only memory (CD-ROM), and so forth. In operation, a general purpose or application-specific processor or processing core loads and executes software in a manner well understood in the art. It should be further understood that the block and flow diagrams may include more or fewer elements, be arranged or oriented differently, or be represented differently. It should be understood that implementation may dictate the block, flow, and/or network diagrams and the number of block and flow diagrams illustrating the execution of embodiments disclosed herein. Further, example embodiments and elements thereof may be combined in a manner not explicitly disclosed herein.

The teachings of all patents, published applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A circuit comprising:
a packet buffer (PB) with at least one queue;
PB write logic configured, in response to a stop command, to mark a start of packet (SoP) word of a packet with a synchronization indicator to produce a marked SoP word written to a queue of the at least one queue of the PB and to write, to descriptor logic, packet-delimiters of words of the packet written to the queue, the stop command identifying the queue; and
PB read logic configured to read from the descriptor logic based on reading the marked SoP word from the queue of the PB and to stop reading from the queue based on reading an active end of packet (EoP) delimiter from the descriptor logic, transmission of the packet from the queue stopped in a graceful manner via the reading stopped, the graceful manner including stopping the transmission at a packet boundary of the packet.

2. The circuit of claim 1, wherein each queue of the at least one queue of the PB is a first-in first-out (FIFO) queue.

3. The circuit of claim 1, wherein the descriptor logic includes a descriptor FIFO for the queue, wherein the PB read logic includes graceful stop logic, and wherein the graceful stop logic is configured to:
read from the queue based on a read grant received for the queue;
initialize a read pointer of the descriptor FIFO based on reading the marked SoP word from the queue;
read from the descriptor FIFO based on the read pointer initialized; and
stop the reading from the queue based on reading the active EoP delimiter from the descriptor FIFO.

4. The circuit of claim 3, wherein the PB read logic includes a delay buffer, wherein the graceful stop logic is further configured to initialize the read pointer by offsetting the read pointer from a base pointer of the descriptor FIFO, the offsetting based on a total number of ongoing reads for the queue represented by the delay buffer, the read pointer initialized to cause a next read from the descriptor FIFO to produce delimiters of a next word to be read from the queue.

5. The circuit of claim 1, wherein the SoP word has an active SoP delimiter, wherein transmission of an EoP word of the packet represents the packet boundary, and wherein the EoP word has the active EoP delimiter.

6. The circuit of claim 1, further comprising the descriptor logic, wherein the PB has a read latency, wherein the descriptor logic includes a descriptor FIFO that corresponds to the queue, wherein the descriptor FIFO has a depth that is based on a total number of words of a maximum transmission unit (MTU) and a total number of cycles, and wherein the total number of cycles represents the read latency of the PB.

7. The circuit of claim 1, wherein the descriptor logic includes a descriptor FIFO that corresponds to the queue and wherein the descriptor FIFO is configured to contain respective SoP and EoP delimiters of each word written to the queue.

8. The circuit of claim 7, wherein the descriptor FIFO is a flip-flop (FF)-based descriptor FIFO and wherein the descriptor logic includes a respective FF-based descriptor FIFO for each queue of the at least one queue of the PB.

9. The circuit of claim 1, wherein the descriptor logic includes a descriptor FIFO for the queue, wherein the PB write logic is configured to push to the descriptor FIFO, with each word written to the queue, respective SoP and EoP delimiters of each word written, starting from a base of the descriptor FIFO, and to stop pushing to the descriptor FIFO in an event the descriptor FIFO is full.

10. The circuit of claim 1, wherein the PB read logic includes graceful stop logic and wherein the graceful stop logic is configured to read from the queue based on a read grant received for the queue and to stop the reading from the queue by ignoring read grants received for the queue.

11. The circuit of claim 1, wherein the PB read logic includes a delay buffer configured to indicate ongoing reads from the PB, wherein a number of entries in the delay buffer is based on a read latency of the PB, and wherein an entry of the delay buffer is configured to represent a queue identifier of a respective queue of the PB for which a read is ongoing.

12. A method comprising:
marking, in response to a stop command, a start of packet (SoP) word of a packet with a synchronization indicator to produce a marked SoP word written to a queue of at least one queue of a packet buffer (PB), the stop command identifying the queue;
writing, to descriptor logic in response to the stop command, packet-delimiters of words of the packet written to the queue of the at least one queue;
reading from the descriptor logic based on reading the marked SoP word from the queue of the PB; and
stopping reading from the queue based on reading an active end of packet (EoP) delimiter from the descriptor logic, transmission of the packet from the queue stopped in a graceful manner via the reading stopped, the graceful manner including stopping the transmission at a packet boundary of the packet.

13. The method of claim 12, wherein each queue of the at least one queue of the PB is a first-in first-out (FIFO) queue.

14. The method of claim 12, wherein the descriptor logic includes a descriptor FIFO for the queue and wherein the method further comprises:
reading from the queue based on a read grant received for the queue;
initializing a read pointer of the descriptor FIFO based on reading the marked SoP word from the queue;
reading from the descriptor FIFO based on the read pointer initialized; and
stopping the reading from the queue based on reading the active EoP delimiter from the descriptor FIFO.

15. The method of claim 14, further comprising initializing the read pointer by offsetting the read pointer from a base pointer of the descriptor FIFO, the offsetting based on a total number of ongoing reads for the queue represented by a delay buffer, the read pointer initialized to cause a next read from the descriptor FIFO to produce delimiters of a next word to be read from the queue.

16. The method of claim 12, wherein the SoP word has an active SoP delimiter, wherein transmission of an EoP word of the packet represents the packet boundary, and wherein the EoP word has the active EoP delimiter.

17. The method of claim 12, wherein the PB has a read latency, wherein the descriptor logic includes a descriptor FIFO that corresponds to the queue, wherein the descriptor FIFO has a depth that is based on a total number of words of a maximum transmission unit (MTU) and a total number of cycles, and wherein the total number of cycles represents the read latency of the PB.

18. The method of claim 12, wherein the descriptor logic includes a descriptor FIFO that corresponds to the queue and wherein writing to the descriptor logic includes writing to the descriptor FIFO.

19. The method of claim 18, wherein the descriptor FIFO is a flip-flop (FF)-based descriptor FIFO and wherein the descriptor logic includes a respective FF-based descriptor FIFO for each queue of the at least one queue of the PB.

20. The method of claim 12, wherein the descriptor logic includes a descriptor FIFO for the queue, wherein writing to the descriptor logic includes pushing to the descriptor FIFO, with each word written to the queue, respective SoP and EoP delimiters of each word written, starting from a base of the descriptor FIFO and wherein the method further comprises stopping the pushing to the descriptor FIFO in an event the descriptor FIFO is full.

21. The method of claim 12, wherein reading from the queue is based on a read grant received for the queue and wherein stopping the reading from the queue includes ignoring read grants received for the queue.

22. An apparatus comprising:
means for marking, in response to a stop command, a start of packet (SoP) word of a packet with a synchronization indicator to produce a marked SoP word written to a queue of at least one queue of a packet buffer (PB), the stop command identifying the queue;
means for writing to descriptor logic in response to the stop command, packet-delimiters of words of the packet written to the queue of the at least one queue,
means for reading from the descriptor logic based on reading the marked SoP word from the queue of the PB; and
means to stop reading from the queue based on reading an active end of packet (EoP) delimiter from the descriptor logic, transmission of the packet from the queue stopped in a graceful manner via the reading stopped, the graceful manner including stopping the transmission at a packet boundary of the packet.

23. A system comprising:
a network interface; and
a device, the device including:
a packet buffer (PB) with at least one queue;
PB write logic configured, in response to a stop command, to mark a start of packet (SoP) word of a packet with a synchronization indicator to produce a marked SoP word written to a queue of the at least one queue of the PB and to write, to descriptor logic, packet-delimiters of words of the packet written to the queue, the stop command identifying the queue; and
PB read logic configured to read from the descriptor logic based on reading the marked SoP word from the queue of the PB and to stop reading from the queue based on reading an active end of packet (EoP) delimiter from the descriptor logic, transmission of the packet from the queue stopped in a graceful manner via the reading stopped, the graceful manner including stopping the transmission at a packet boundary of the packet.

24. The system of claim 23, wherein the system is a server of at least one server of a data center and wherein the device is a system-on-chip (SoC).

25. A hardware description language (HDL) design structure encoded on a machine-readable data storage medium, the HDL design structure comprising elements that when processed in a computer-aided design system generate a machine-executable representation of a device, wherein the HDL design structure comprises:
a packet buffer (PB) with at least one queue;
PB write logic configured, in response to a stop command, to mark a start of packet (SoP) word of a packet with a synchronization indicator to produce a marked SoP word written to a queue of the at least one queue of the PB and to write, to descriptor logic, packet-delimiters of words of the packet written to the queue, the stop command identifying the queue; and
PB read logic configured to read from the descriptor logic based on reading the marked SoP word from the queue of the PB and to stop reading from the queue based on reading an active end of packet (EoP) delimiter from the descriptor logic, transmission of the packet from the queue stopped in a graceful manner via the reading stopped, the graceful manner including stopping the transmission at a packet boundary of the packet.
